(19) United States
(12) Patent Application Publication
(10) Pub. No.: US 2024/0103372 A1
(43) Pub. Date: Mar. 28, 2024

(54) EXPOSURE APPARATUS

(71) Applicant: NIKON CORPORATION, Tokyo (JP)

(72) Inventors: Masaki KATO, Yokohama-shi (JP); Yasushi MIZUNO, Saitama-shi (JP)

(73) Assignee: NIKON CORPORATION, Tokyo (JP)

(21) Appl. No.: 18/528,903

(22) Filed: Dec. 5, 2023

Related U.S. Application Data
(63) Continuation of application No. PCT/JP2022/027199, filed on Jul. 11, 2022.

(30) Foreign Application Priority Data
Jul. 12, 2021 (JP) 2021-115325

(51) Int. Cl. G03F 7/20

(52) U.S. Cl. CPC G03F 7/20

(57) ABSTRACT

An exposure apparatus includes an exposure module that includes a spatial light modulator and projects and exposes pattern light generated by the spatial light modulator onto a substrate, and a determination unit configured to, when a plurality of substrates scheduled to be arranged on a substrate holder include a first substrate having a defect, determine a plurality of substrates to be arranged on the substrate holder from the plurality of substrates scheduled to be arranged on the substrate holder, based on a predetermined handling method for the first substrate.

### CROSS-REFERENCE TO RELATED APPLICATION

This application is based upon and claims the benefit of priority of the prior International Patent Application No. PCT/JP2022/027199, filed on Jul. 11, 2022, the entire contents of which are incorporated herein by reference.

### FIELD

The present disclosure relates to an exposure apparatus.

### BACKGROUND

In recent years, packages of semiconductor devices called FO-WLP (Fan Out Wafer Level Package) and FO-PLP (Fan Out Plate Level Package) have been known as disclosed in, for example, Japanese Patent Application Laid-Open No. 2018-081281 (Patent Document 1).

For example, in the manufacture of the FO-WLP, a plurality of semiconductor chips are arranged on a wafer-shaped support substrate and are fixed with a mold material such as a resin to form a pseudo wafer, and a rewiring layer for connecting pads of the semiconductor chips to each other is formed using an exposure apparatus.

### SUMMARY

It has been studied to place a plurality of wafers on the substrate holder of the exposure apparatus and form a rewiring layer on each of the plurality of wafers. However, there are many points to be considered, such as how to cope with a case where a wafer having a defect is included in the plurality of wafers.

In one aspect of the present disclosure, there is provided an exposure apparatus including: an exposure module that includes a spatial light modulator and projects and exposes pattern light generated by the spatial light modulator onto a substrate; and a determination unit configured to, when a plurality of substrates scheduled to be arranged on a substrate holder include a first substrate having a defect, determine a plurality of substrates to be arranged on the substrate holder from the plurality of substrates scheduled to be arranged on the substrate holder, based on a predetermined handling method for the first substrate.

The configuration of the embodiment described later may be appropriately modified, and at least a part of the configuration may be replaced with another configuration. Further, the constituent elements whose arrangement is not particularly limited are not limited to the arrangement disclosed in the embodiment, and can be arranged at positions where the functions can be achieved.

### BRIEF DESCRIPTION OF DRAWINGS

FIG. 1 is a top view illustrating an outline of a wiring pattern formation system according to an embodiment;

FIG. 2 is a perspective view schematically illustrating a configuration of an exposure apparatus according to the embodiment;

FIG. 3A and FIG. 3B are diagrams for describing wiring patterns formed by the wiring pattern formation system;

FIG. 4 is a view for describing modules arranged on an optical surface plate;

FIG. 5A illustrates an optical system of an exposure module, FIG. 5B schematically illustrates a DMD, FIG. 5C illustrates the DMD when the power is off, FIG. 5D is a view for describing a mirror in an ON state, and FIG. 5E is a view for describing a mirror in an OFF state;

FIG. 6 illustrates an example of arrangement of projection regions of a plurality of exposure modules;

FIG. 7 is an enlarged view of the vicinities of the exposure modules;

FIG. 8A is a schematic view illustrating a wafer in a state where all chips are arranged at design positions, and FIG. 8B is a schematic view illustrating a wafer in which chips are arranged at positions shifted from design positions;

FIG. 9A to FIG. 9C are diagrams for describing predetermined measurement points on chips;

FIG. 10A is a view illustrating chips fixed to a wafer with being shifted from design positions, FIG. 10B is an enlarged view of a partial wiring portion, and FIG. 10C is a view illustrating a state where chips arranged at positions shifted from the design positions are connected by wiring patterns;

FIG. 11 is a functional block diagram illustrating a functional configuration of a control system;

FIG. 12 is a conceptual diagram of a procedure for forming wiring patterns of the FO-WLP in the exposure apparatus;

FIG. 13 illustrates the arrangement of wafers in case 3;

FIG. 14A and FIG. 14B illustrates the arrangement of wafers in case 4;

FIG. 15A and FIG. 15B illustrates the arrangement of wafers in case 5;

FIG. 16 illustrates another example of the arrangement of projection regions of a plurality of exposure modules; and

FIG. 17A and FIG. 17B are diagrams for describing countermeasure 4 in a case where the DMD has a defective element.

### DESCRIPTION OF EMBODIMENTS

A wiring pattern formation system 500 according to an embodiment will be described with reference to the drawings. In the following description, a substrate P indicates a rectangular substrate, and a wafer-shaped substrate is referred to as a wafer WE. Further, in the following description, the normal direction of the substrate P or the wafer WF placed on a substrate holder PH described later is defined as the Z-axis direction, the direction in which the substrate P or the wafer WF is relatively scanned with respect to a spatial light modulator (SLM) in a plane orthogonal to the Z-axis direction is defined as the X-axis direction, the direction orthogonal to the Z-axis and the X-axis is defined as the Y-axis direction, and the rotation (tilt) directions around the X-axis, the Y-axis, and the Z-axis are defined as the θx, θy, and θz directions, respectively. Examples of the spatial light modulator include a liquid crystal element, a digital micromirror device (DMD), and a magneto-optic spatial light modulator (MOSLM). An exposure apparatus EX according to the present embodiment includes a DMD 204 as the spatial light modulator, but may include other spatial light modulators.

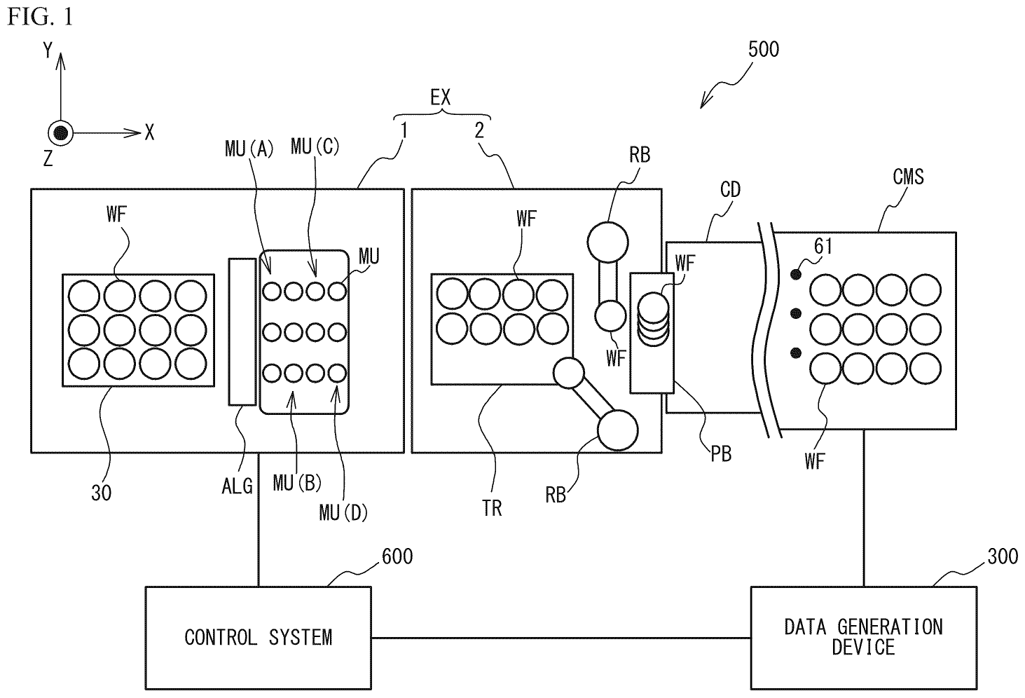

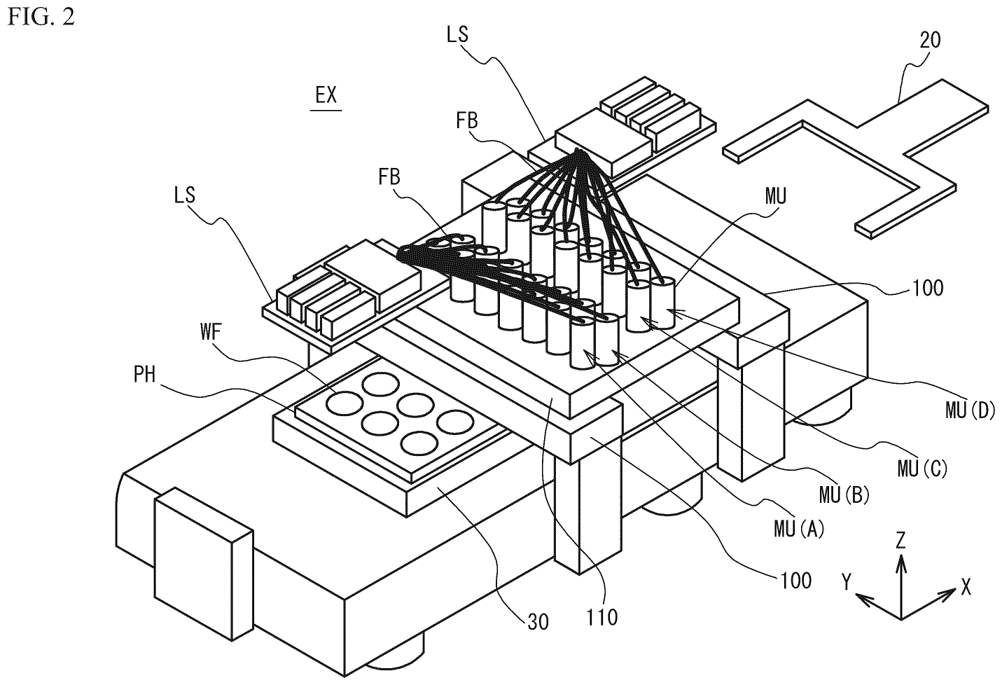

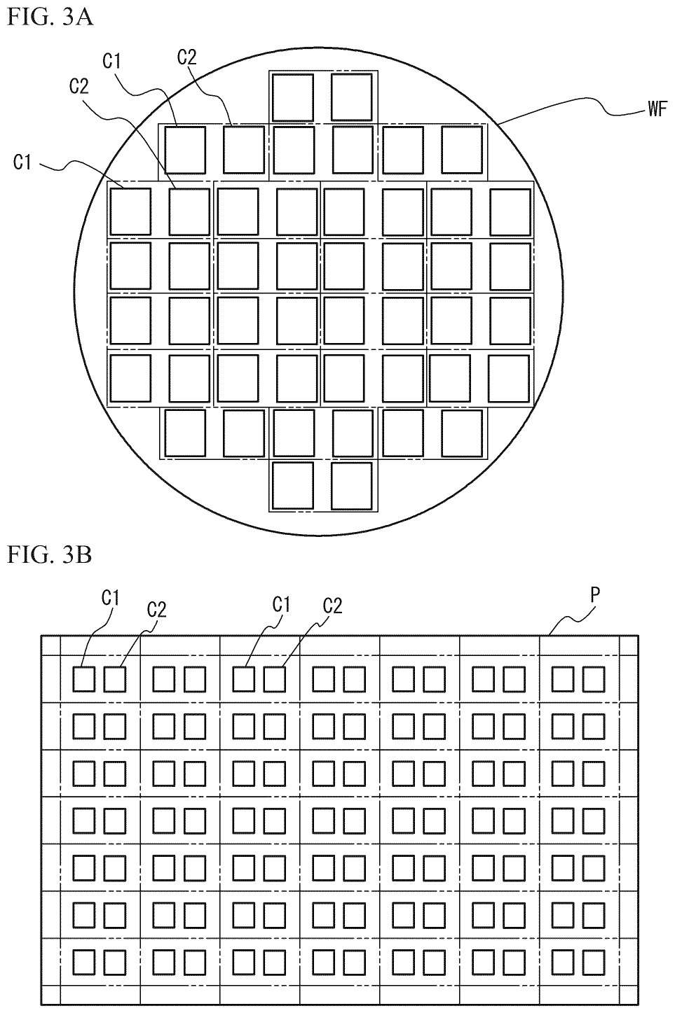

FIG. 1 is a top view illustrating an outline of the wiring pattern formation system 500 for the FO-WLP and FO-PLP, according to an embodiment. FIG. 2 is a perspective view schematically illustrating a configuration of the exposure apparatus EX included in the wiring pattern formation system 500. FIG. 3A and FIG. 3B are diagrams for describing wiring patterns formed by the wiring pattern formation system.

The wiring pattern formation system 500 is a system for forming wiring patterns for connecting chips arranged on the wafer WF as illustrated in FIG. 3A or for connecting chips arranged on the substrate P as illustrated in FIG. 3B.

In the present embodiment, wiring patterns each connecting chips C1 and C2 included in each of sets of chips (indicated by double-dotted lines) arranged on the wafer WF or the substrate P are formed. FIG. 3A and FIG. 3B illustrate the case where the number of chips included in each set is two, but the number of chips included in each set may be three or more. In the following description, a case where wiring patterns connecting chips arranged on the wafer WF are formed will be described.

As illustrated in FIG. 1, the wiring pattern formation system 500 includes a chip measurement station CMS, a coater/developer device CD, the exposure apparatus EX, a data generation device 300, and a control system 600. The wiring pattern formation system 500 also includes a control device 600A including the control system 600 and the data generation device 300, and the control device 600A controls the exposure apparatus EX.

The chip measurement station CMS includes a plurality of measurement microscopes 61, and the measurement microscopes 61 measure the positions of the chips by measuring predetermined measurement points on the chips in each set on different wafers WF. The measurement microscopes 61 may measure the positions of the predetermined measurement points on chips in different sets on the same wafer WF.

In FIG. 1, 4 rows×3 columns of the wafers WF are arranged in the chip measurement station CMS, and the predetermined measurement points on the chips are measured, but the number of the wafers WF arranged in the chip measurement station CMS is not limited to 4 rows×3 columns. The chip measurement station CMS can measure the predetermined measurement points on the chips of an arbitrary number of wafers WF, for example, 4 wafers×1 column or 3 wafers×2 columns. The chip measurement station CMS may measure the wafers WF one by one. The position measurement results of the predetermined measurement points are transmitted to the data generation device 300.

The data generation device 300 calculates the positions of all the pads based on the position measurement results of the predetermined measurement points received from the chip measurement station CMS, and generates wiring pattern data used to form wiring patterns each connecting the chips included in each set of the wafer WF for each wafer WF based on the calculation results. The calculation of the pad positions and the generation of the wiring pattern data will be described in detail later. The wiring pattern data generated by the data generation device 300 is transferred to the control system 600.

The control system 600 generates drawing (exposure) data based on the wiring pattern data for each wafer WF, and controls exposure modules MU, which will be described later, based on the drawing data. The detailed configuration of the control system 600 will be described later.

On the other hand, the wafer WF for which the measurement of the positions of the predetermined measurement points on the chips has been completed in the chip measurement station CMS is carried into the coater/developer device CD.

The coater/developer device CD coats the wafer WF with a photosensitive resist. The wafer WF coated with the resist is carried into a buffer section PB that can stock a plurality of wafers WF. The buffer section PB also serves as a delivery port for the wafer WF.

More specifically, the buffer section PB includes a carry-in section and a carry-out section. The wafers WF coated with a resist are carried into the carry-in section one by one from the coater/developer device CD. The wafers WF coated with the resist are carried into the carry-in section one by one at predetermined time intervals from the coater/developer device CD, and a plurality of the wafers WF are collectively mounted on a tray TR described later, and therefore, the carry-in section functions as a buffer for storing the wafers WF.

The carry-out section functions as a buffer when the exposed wafer WF is carried out to the coater/developer device CD. The coater/developer device CD can take out the exposed wafers WF only one by one. Thus, the tray TR on which a plurality of exposed wafers WF are placed is placed in the carry-out section. This allows the coater/developer device CD to take out the exposed wafers WF one by one from the tray TR.

The exposure apparatus EX includes a main unit 1 and a substrate exchange unit 2. As illustrated in FIG. 1, a robot RB is installed in the substrate exchange unit 2. The robot RB arranges a plurality of wafers WF placed in the buffer section PB on one tray TR.

As illustrated in FIG. 1, in the present embodiment, it is possible to place 4 rows×3 columns of the wafers WF on the substrate holder PH, which will be described later. The tray TR according to the present embodiment is a lattice-shaped tray that can place 4 rows×3 columns of the wafers WF onto a substrate stage 30. The number of the wafers WF that can be placed on the tray TR is not limited to 12, and the tray TR may be a tray on which 4 rows×1 column of the wafers WF can be placed, for example. In this case, when 4 rows×3 columns of the wafers WF are placed on the substrate holder PH, the wafers WF are placed on the substrate stage 30 in three separate steps. The arrangement of the wafers WF placed on the substrate holder PH is not limited to 4 rows×3 columns, and may be appropriately set based on the size of the wafer WF, the planar area of the substrate holder PH, and the like.

As illustrated in FIG. 2, the substrate exchange unit 2 includes an exchange arm 20. The exchange arm 20 carries in and out the wafers WF (more specifically, the tray TR on which a plurality of wafers WF are placed) to and from the substrate holder PH of the substrate stage 30, and the exchange arm 20 carries in and out the wafers WF to and from the substrate holder PH of the substrate stage 30. The substrate holder PH is not illustrated in the drawings other than FIG. 2.

In general, two exchange arms 20, i.e., a carry-in arm for carrying in the tray TR and a carry-out arm for carrying out the tray TR are arranged. Thus, the tray TR can be replaced at high speed. When the wafer WF is carried in, substrate exchange pins (not illustrated) support the lattice-shaped tray TR. When the substrate exchange pins are lowered, the tray TR is sunk into a groove (not illustrated) formed in the substrate stage 30, and the wafers WF are sucked and held by the substrate holder PH on the substrate stage 30.

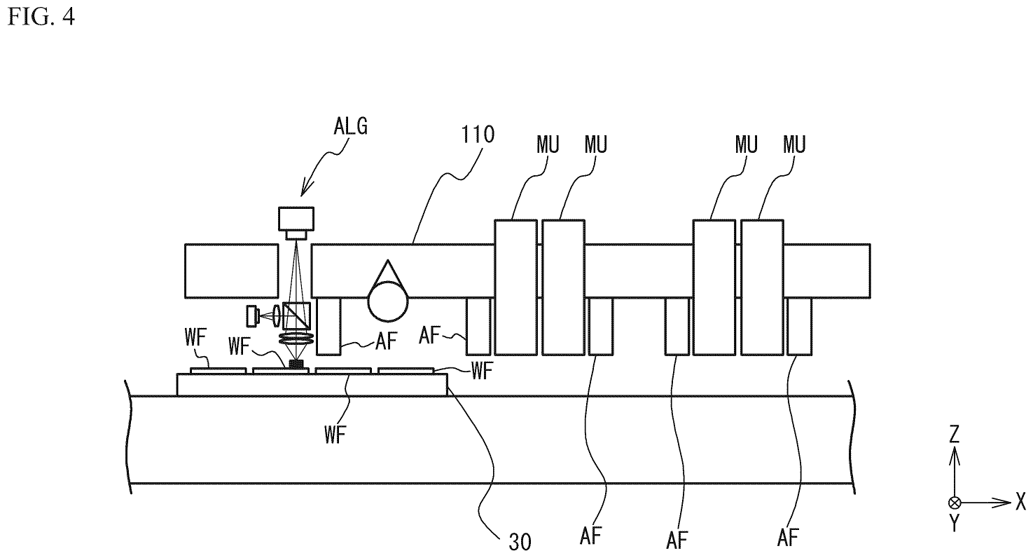

When the wafer WF is sucked by the substrate holder PH, an alignment system ALG mounted on an optical surface plate 110 measures the positions of the predetermined measurement points on the chips arranged on the wafer WF. FIG. 4 is a view for describing modules arranged on the optical surface plate 110.

As illustrated in FIG. 4, a plurality of exposure modules MU, autofocus systems AF, and the alignment system ALG are arranged on the optical surface plate 110 kinematically supported on a column 100.

As illustrated in FIG. 2, the exposure modules MU are arranged in the X-axis direction and the Y-axis direction. Here, groups of the exposure modules MU arranged in the Y-axis direction are defined as exposure module groups MU(A), MU(B), MU(C), and MU(D). In the present embodiment, the exposure module groups are arranged in four rows in the X-axis direction, but the number of exposure module groups is not limited to four, and may be three or less, or five or more.

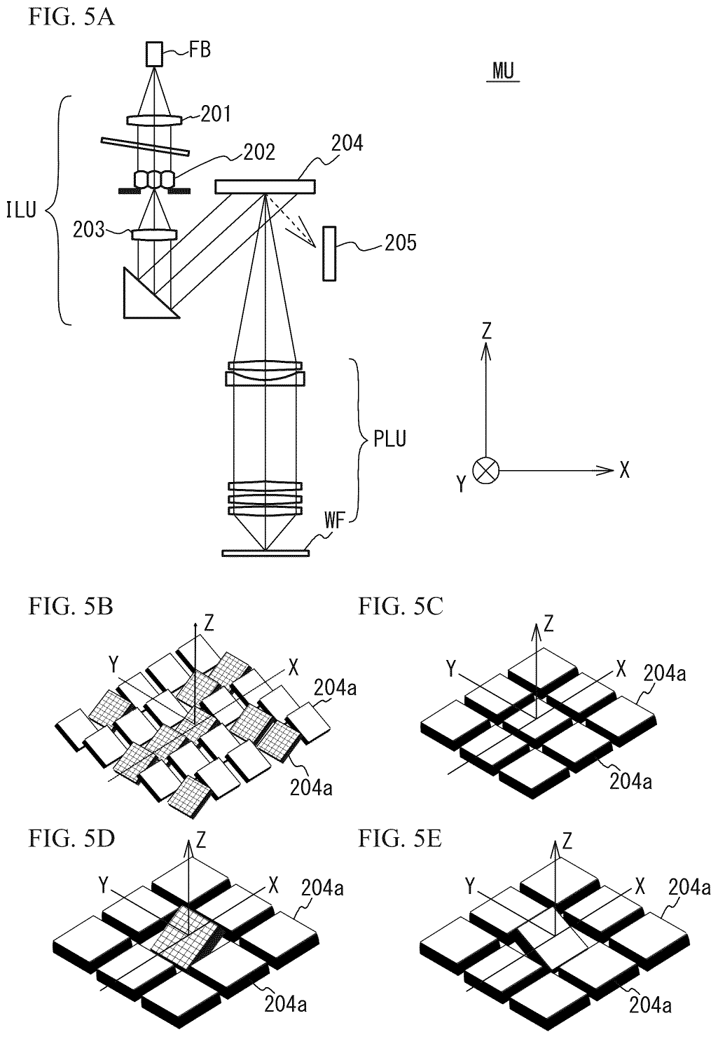

FIG. 5A illustrates an optical system of the exposure module MU. The exposure module MU includes an illumination module ILU, the DMD 204, and a projection module PLU. The illumination module ILU includes, for example, a collimator lens 201, a fly-eye lens 202, and a main condenser lens 203.

The laser light emitted from a light source LS (see FIG. 2) is taken into the exposure module MU through a delivery fiber FB. The laser light passes through the collimator lens 201, the fly-eye lens 202, and the main condenser lens 203, and illuminates the DMD 204 substantially uniformly.

FIG. 5B schematically illustrates the DMD 204, and FIG. 5C illustrates the DMD 204 when the power is off. In FIG. 5B to FIG. 5E, the mirrors in the ON state are indicated by hatching.

The DMD 204 has a plurality of micromirrors 204a of which the reflection angles can be controlled to be change. Each micromirror 204a is turned on by tilting around the Y-axis. FIG. 5D illustrates a case where only the center micromirror 204a is in the ON state, and other micromirrors 204a are in the neutral state (a state other than the ON state and the OFF state). Each micromirror 204a is turned off by tilting around the X-axis. FIG. 5E illustrates a case where only the center micromirror 204a is turned off and other micromirrors 204a are in the neutral state. The DMD 204 generates an exposure pattern of wiring lines connecting the chips (hereinafter referred to as a wiring pattern) by switching the ON and OFF states of each micromirror 204a.

The illumination light reflected by the mirror in the OFF state is absorbed by an OFF light absorbing plate 205 as illustrated in FIG. 5A. The projection module PLU has a magnification for projecting one pixel of the DMD 204 in a predetermined size, and the magnification can be slightly corrected by focusing by Z-axis driving of the lens and driving some of the lenses. Further, the DMD 204 itself can be driven in the X direction, the Y direction, and the θz direction by controlling a fine movement stage (not illustrated) on which the DMD 204 is mounted, and corrects, for example, the deviation of the substrate holder PH from the target value.

Although the DMD 204 has been described as an example of the spatial light modulator and thus as a reflective type that reflects laser light, the spatial light modulator may be a transmissive type that transmits laser light or a diffractive type that diffracts laser light. The spatial light modulator can modulate the laser light spatially and temporally.

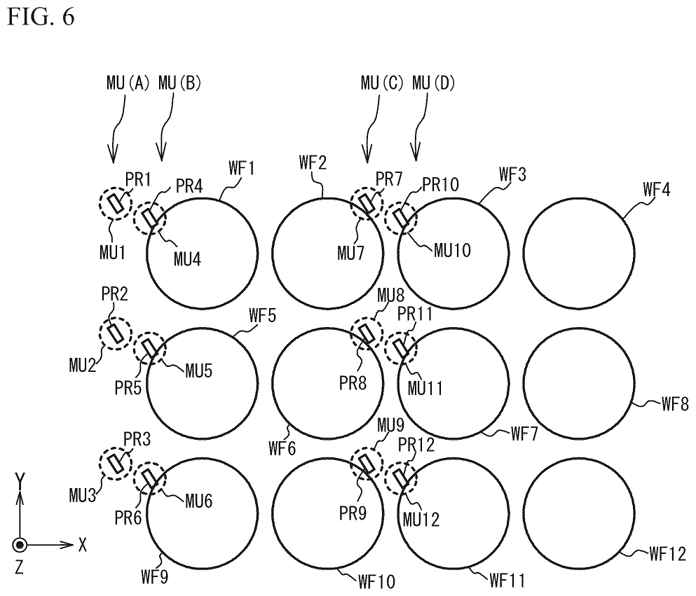

FIG. 6 illustrates an example of the arrangement of the projection regions of the exposure modules MU. In FIG. 6, the exposure module MU is indicated by a dotted line, and a projection region PR where the exposure module MU projects a wiring pattern onto the wafer W F is indicated by a solid line.

As illustrated in FIG. 6, the exposure module group MU(A) includes exposure modules MU1 to MU3 arranged in the Y-axis direction, the exposure module group MU(B) includes exposure modules MU4 to MU6 arranged in the Y-axis direction, the exposure module group MU(C) includes exposure modules MU7 to MU9 arranged in the Y-axis direction, and the exposure module group MU(D) includes exposure modules MU10 to MU12 arranged in the Y-axis direction.

The exposure modules MU1 to MU12 project and expose the wiring pattern images on the wafers WF based on drawing data MD1 to MD12 transferred from the control system 600, respectively.

In the example of FIG. 6, among the wafers WF1 to WF12 placed on the substrate holder PH, the exposure modules MU1 and MU4 handle exposure of the wafers WF1 and WF2, and the exposure modules MU7 and MU10 handle exposure of the wafers WF3 and WF4. The exposure modules MU2 and MU5 handle exposure of the wafers WF5 and WF6, and the exposure modules MU8 and MU11 handle exposure of the wafers WF7 and WF8. The exposure modules MU3 and MU6 handle exposure of the wafers WF9 and WF10, and the exposure modules MU9 and MU12 handle exposure of the wafers WF11 and WF12. By managing a plurality of wafers in this manner, each wafer can be appropriately handled by a plurality of exposure modules.

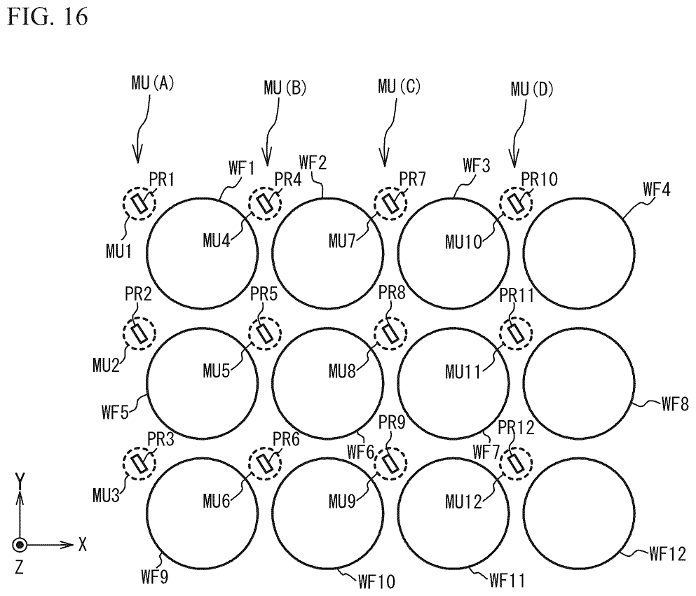

For example, when a plurality of wafers are managed by numbers (WF1 to WF12), the numbers WF1, WF2, . . . , WF12 are assigned in the order in which the wafers are placed on the chip measurement station CMS, and the positions of the predetermined measurement points on the chips of the wafers are measured. When a defect of a wafer is detected in the chip measurement station CMS, the number (for example, WF7) assigned to the defective wafer is managed. The wafers for which the measurement has been completed are carried into the coater/developer device DC in the order of WF1, WF2, . . . , WF12, are taken out from the coater/developer device DC in the order of WF1, WF2, . . . , WF12, and are placed in the buffer section PB (carry-out section). When 4 rows×3 columns of wafers are arranged on the substrate stage 30, the positions of 4 rows×3 columns of the wafers are associated with the numbers of WF1, WF2, . . . , WF12. For example, the wafer WF1 corresponds to the position in the first row and first column, the waver WF2 corresponds to the position in the first row and second column, the wafer WF3 corresponds to the position in the first row and third column, the wafer WF4 corresponds to the position in the first row and fourth column, the wafer WF5 corresponds to the position in the second row and first column, the wafer WF6 corresponds to the position in the second row and second column, the wafer WF7 corresponds to the position in the second row and third column, the wafer WF8 corresponds to the position in the second row and fourth column, the wafer WF9 corresponds to the position in the third row and first column, the wafer WF10 corresponds to the position in the third row and second column, the wafer WF11 corresponds to the position in the third row and third column, and the wafer WF12 corresponds to the position in the third row and fourth column. By the chip measurement station CMS notifying the exposure apparatus EX of the number (for example, WF7) of the defective wafer, various countermeasures described later can be taken for the defective wafer based on the correspondence relationship between the wafer and the exposure module. For example, in FIG. 16, the exposure modules MU1, MU4, MU7, MU10, MU2, MU5, MU8, MU11, MU3, MU6, MU9, and MU12 correspond to the wafers WF1, WF2, . . . , WF12, respectively, and various countermeasures described later, such as not performing the exposure on the defective wafer WF7 by the exposure module MU8 can be taken. Further, it is also possible not to place a defective wafer on the substrate holder PH of the exposure apparatus EX, and for example, in FIG. 16, various countermeasures described later, such as not performing exposure by the exposure module MU8 scheduled to handle exposure of the defective wafer WF7 can be taken.

The arrangement of the exposure modules MU is not limited to the example illustrated in FIG. 6. The number of exposure module groups, the number of exposure modules MU included in each exposure module group, the wafer WF to be exposed by the exposure module MU, and the like can be freely selected.

Returning to FIG. 4, the autofocus systems AF are arranged so as to sandwich the exposure module MU. Thus, the measurement can be performed by the autofocus systems AF before the exposure operation for projecting and exposing the image of the wiring pattern connecting the chips arranged on the wafer WF, regardless of the scanning direction of the wafer WF.

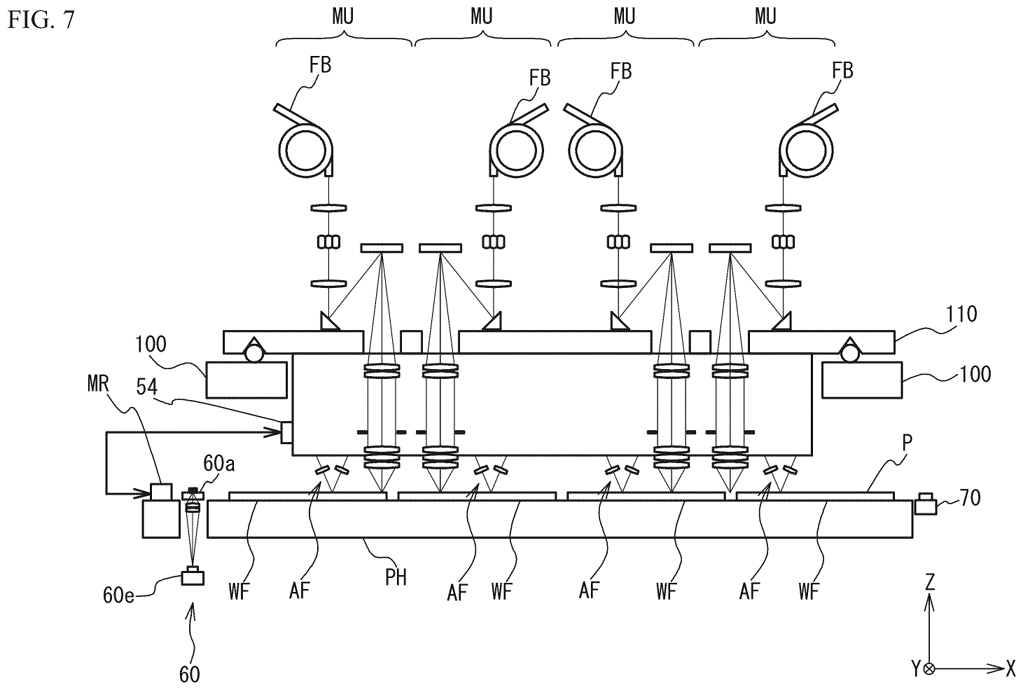

The alignment system ALG measures the positions of the wafers WF placed on the substrate holder PH of the substrate stage 30 before the start of exposure, with reference to the reference mark 60a (see FIG. 7) of an alignment device 60. Normally, in the measurement of the position of each wafer WF, the number of measurement points and the arrangement of the measurement points are determined so that six parameters of the wafer WF placed on the substrate holder PH, i.e., the X-direction shift (X), the Y-direction shift (Y), the rotation (Rot), the X-direction magnification (X_Mag), the Y-direction magnification (Y_Mag), and the orthogonality (Oth) can be calculated. Based on the measurement results by the alignment system ALG, the positional shift of the wafer WF with respect to the substrate holder PH is detected.

Here, when the position of the chip is shifted from the position defined in the wiring pattern data generated by the data generation device 300 due to the rotation of the wafer WF around the Z axis at the time of placing the wafer WF on the substrate holder PH, the chips will not be connected correctly if the wiring lines are formed using the wiring pattern data.

In this case, a correction unit 605 included in the control system 600 described later corrects the positional shift of the wafer WF from the design value by shifting the projected position of the wiring pattern image. More specifically, the projected position of the image of the wiring pattern is shifted by controlling at least one of the following: the driving of the fine movement stage that is movable in the X direction, the Y direction, and the θz direction and on which the DMD 204 is mounted, and the adjustment of the optical system of the projection module PLU. This makes it possible to correct the positional shift of the wafer WF from the design value, and to smoothly shift to exposure and form wiring lines connecting chips because there is no need to rewrite the drawing data.

FIG. 7 is an enlarged view of the vicinities of the exposure modules MU. As illustrated in FIG. 7, a fixed mirror 54 for measuring the position of the substrate holder PH is provided near the exposure module MU.

Further, as illustrated in FIG. 7, the alignment device 60 is provided on the substrate holder PH. The alignment device 60 includes a reference mark 60a, a two-dimensional image sensor 60e, and the like. The alignment device 60 is used for measurement and calibration of the positions of various modules, and is also used for calibration of the alignment system ALG arranged on the optical surface plate 110.

The measurement and calibration of the position of each module is performed by projecting a DMD pattern for calibration onto the reference mark 60a of the alignment device 60 and measuring the relative position between the reference mark 60a and the DMD pattern.

Further, the calibration of the alignment system ALG can be performed by measuring the reference mark 60a of the alignment device 60 by the alignment system ALG. That is, the positions of the alignment system ALG can be obtained by measuring the reference mark 60a of the alignment device 60 by the alignment system ALG. Further, the relative position between the alignment system ALG and the exposure module MU can be obtained using the reference mark 60a.

Although the alignment system ALG measures the positions of the wafers WF placed on the substrate holder PH before the start of exposure, with reference to the reference mark 60a (see FIG. 7) of the alignment device 60, the measurement by the alignment system ALG can be omitted if the positional relationship between the substrate holder PH and the wafers WF does not change.

The substrate holder PH is also provided with a moving mirror MR used to measure the position of the substrate holder PH, a DM monitor 70, and the like.

(Data Generation Device 300)

Next, the data generation device 300 will be described. The data generation device 300 is, for example, a personal computer or a server computer. The data generation device 300 receives the position measurement results of the predetermined measurement points on the chips provided on the wafer WF from the chip measurement station CMS. The data generation device 300 calculates the positions of all the pads of each chip provided on the wafer WF based on the received position measurement results. The data generation device 300 determines wiring patterns for connecting the pads based on the calculation results of the pad positions of each chip, and generates control data (wiring pattern data) for causing the DMD 204 to form the determined wiring patterns. In the present embodiment, the data generation device 300 generates wiring pattern data for each wafer WF and transfers the wiring pattern data to the control system 600.

The reason why the data generation device 300 determines the wiring patterns for connecting the pads based on the calculation results of the positions of the pads of each chip will be described.

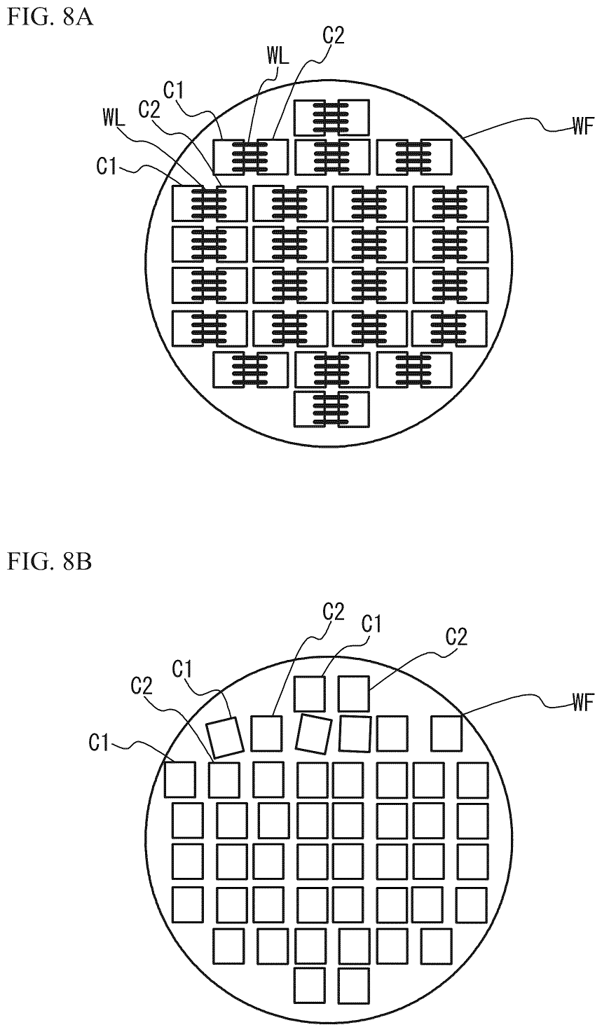

FIG. 8A is a schematic view illustrating the wafer WF in a state where all chips are arranged at positions in design (hereinafter, referred to as design positions). As illustrated in FIG. 8A, a wiring pattern WL connecting the chip C1 and the chip C2 is exposed (formed) by the exposure apparatus EX. Here, in the FO-WLP, since the chips are fixed with a mold material such as a resin on the wafer WF, as illustrated in FIG. 8B, the position of each chip may be shifted from the design position. In this case, if the wiring pattern is exposed by controlling the DMD 204 using pattern data for forming the wiring pattern that connects the chips at the design positions (hereinafter, referred to as design value data), the wiring pattern may be shifted from the positions of the pads, and a connection defect or a short circuit may occur.

Therefore, in the present embodiment, the data generation device 300 calculates the positions of all the pads on the chip based on the position measurement results acquired from the chip measurement station CMS, and generates wiring pattern data for forming a wiring pattern that can connect the actual pads.

(Generation of Wiring Pattern Data)

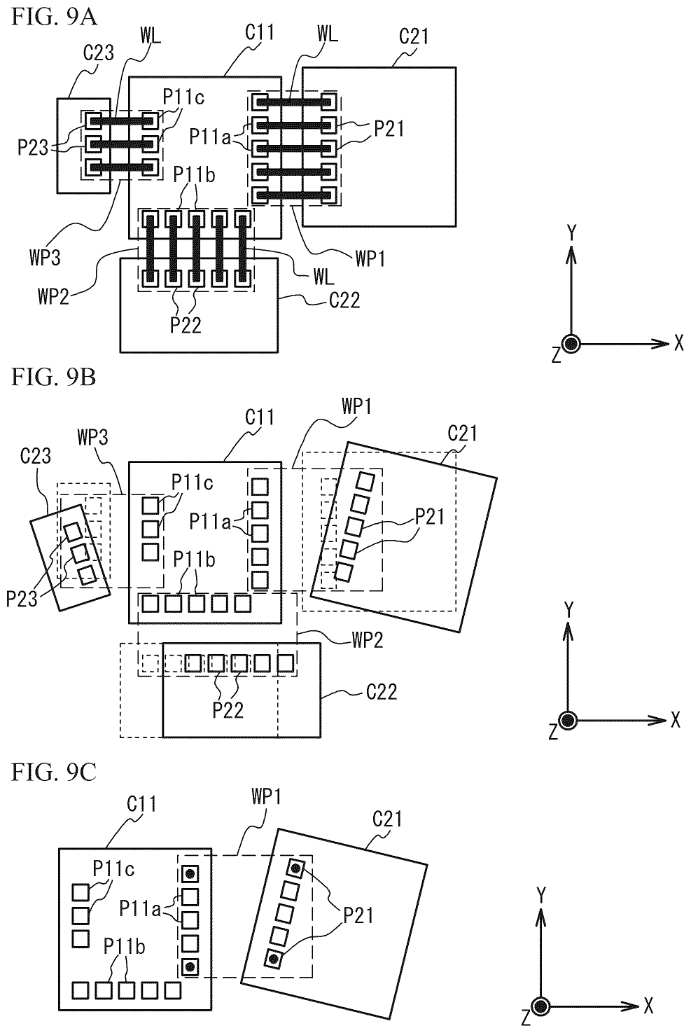

The generation of the wiring pattern data will be described. First, a description will be given of the predetermined measurement points on the chip, which are measured by the measurement microscopes 61 in the chip measurement station CMS. FIG. 9A to FIG. 9C are diagrams for describing the predetermined measurement points on the chips. FIG. 9A illustrates a case where the chips at the design positions are connected to each other by the wiring patterns WL.

As illustrated in FIG. 9A, a case where a chip C11 and each of chips C21 to C23 are connected to each other will be described. More specifically, pads P11a of the chip C11 are connected to pads P21 included in the chip C21, pads P11b of the chip C11 are connected to pads P22 included in the chip C22, and pads P11c of the chip C11 are connected to pads P23 included in the chip C23. In this case, the data generation device 300 generates wiring pattern data for each of a partial wiring portion WP1 where the pads P11a of the chip C11 are connected to the pads P21 of the chip C21, a partial wiring portion WP2 where the pads P11b of the chip C11 are connected to the pads P22 of the chip C22, and a partial wiring portion WP3 where the pads P11c of the chip C11 are connected to the pads P23 of the chip C23.

FIG. 9B is a diagram illustrating an example of the chips C11 and C21 to C23 fixed to the wafer WF in a state of being shifted from the design positions. As illustrated in FIG. 9B, a case where the chips C21 to C23 are fixed to the wafer WF with being shifted from the design positions indicated by dotted lines is considered. In this case, the measurement microscope 61 measures the positions of two pads located at both ends in the arrangement direction of the pads, for each of the two chips included in each of the partial wiring portion WP1, the partial wiring portion WP2, and the partial wiring portion WP3.

The partial wiring portion WP1 will be described as an example. FIG. 9C is a diagram illustrating the pads P11a of the chip C11 and the pads P21 of the chip C21 included in the partial wiring portion WP1.

In the partial wiring portion WP1, the measurement microscope 61 measures the positions of two pads P11a (indicated by black circles in FIG. 9C) located at both ends in the arrangement direction of the pads P11a (Y direction in FIG. 9C) among the pads P11a of the chip C11. That is, the predetermined measurement points on the chip C11 are two pads P11a located at both ends in the arrangement direction of the pads P11a. The measurement microscope 61 measures the positions of two pads P21 (indicated by black circles in FIG. 9C) located at both ends in the arrangement direction of the pads P21 among the pads P21 of the chip C21. That is, the predetermined measurement points on the chip C21 are two pads P21 located at both ends in the arrangement direction of the pads P21. The positions of the pads P11a located at both ends and the positions of the pads P21 located at both ends may be calculated from the amount of movement caused by the movement of the substrate stage 30, or may be measured by imaging the pads P11a located at both ends and the pads P21 located at both ends at once by increasing the field of view of the measurement microscope 61.

Next, the calculation of the pad positions and the generation of the wiring pattern data will be described.

First, the data generation device 300 calculates the positions of all the pads: the pads P11a of the chip C11 and the pads P21 of the chip C21 from the positions of the four pads measured as described above.

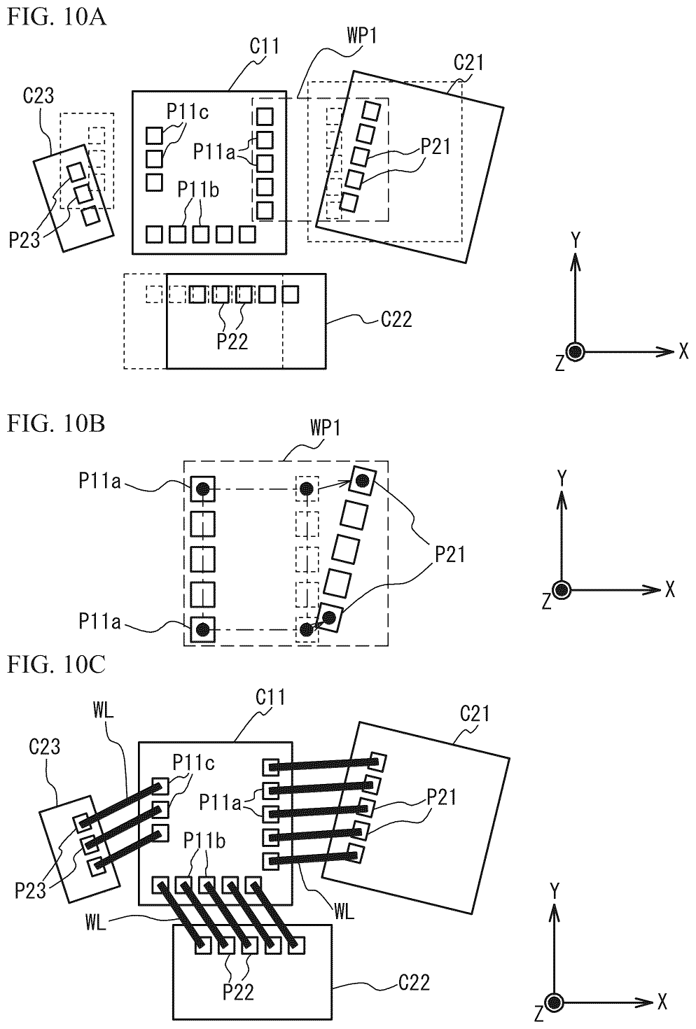

FIG. 10A is a diagram illustrating the chip C11 and the chips C21 to C23 fixed to the wafer WF with being shifted from the design positions, and FIG. 10B is an enlarged view of the partial wiring portion WP1. In the example of FIG. 10A, the chip C11 is located at the design position, but the chips C21 to C23 are fixed at positions shifted from the design positions. Therefore, as illustrated in FIG. 10B, the pads P21 are at positions shifted from the design positions of the pads P21 indicated by dotted lines.

As indicated by a chain line in FIG. 10B, a straight line connecting the pads P11a and the pads P21 of the measurement points at the design positions has a rectangular shape. The data generation device 300 calculates the positions of all the pads P11a and P21 existing in the partial wiring portion WP1 from the relationship between the coordinates of the four corners of the rectangle formed by a straight line connecting the pads P11a and P21 of the measurement points in the design positions and the coordinates of the pads P11a and P21 of the measurement points in the partial wiring portion WP1 measured by the measurement microscope 61.

The data generation device 300 generates wiring pattern data for the partial wiring portion WP1 based on the calculated positions of the pads P11a and P21. Further, the same process is performed on other partial wiring portions WP2 and WP3. Thus, as illustrated in FIG. 10C, the chip C11 and each of the chips C21 to C23 are connected to each other by the wire patterns WL, respectively.

The data generation device 300 repeats the above process to generate wiring pattern data for connecting the chips arranged on each wafer WF for each wafer WE. The generated wiring pattern data is stored in a wiring pattern data storage unit 601 included in the control system 600 described later. The wiring pattern data storage unit 601 is, for example, a solid state drive (SSD).

In the generation of the wiring pattern data, if data other than the partial wiring portion (data for a region where the wiring pattern is not required to be formed) is also generated, it may take time to generate and transfer the wiring pattern data. Therefore, data for a portion corresponding to the partial wiring portion may be generated as wiring pattern data and transferred to the wiring pattern data storage unit 601 included in the control system 600. This partial wiring portion is obtained by adding, in advance, the placement error of each chip to at least a position registered in advance as a design value. This reduces the data amount of the wiring pattern data, thereby reducing the time required to generate and transfer the wiring pattern data.

In this case, for example, template data that sets all micromirrors 204 to the OFF state or ON state in the DMD 204 is prepared in the drawing data generation unit 602 described later, and the data of the portion corresponding to the partial wiring portion is rewritten. In this case, whether the micromirrors 204a are brought into the OFF state or ON state may be switched depending on the recipe. For example, the micromirrors 204a may be switched between the OFF and ON states depending on the type of resist used. For example, when exposure is performed using a resist such as a positive resist so that a wiring portion is left by etching, it is necessary to cause the micromirrors 204a corresponding the region other than the region to be left as the wiring portion to be in the ON state, whereas when a negative resist is used, it is necessary to cause the micromirrors 204a corresponding to the region other than the region to be left as the wiring portion to be in the OFF state. That is, even if the exposure pattern is the same, the ON/OFF data may be changed according to the type of resist applied to the wafer. Further, when a plurality of sets are processed with the same recipe, there is a possibility that a failure such as sticking of each micromirror 204a may occur by using only the DMD 204 in the same region. In this case, the pattern on the DMD 204 is shifted from the original position by, for example, one column in the +Y direction. This changes the micromirrors 204a to be used, and therefore, a failure is less likely to occur. However, since the pattern on the DMD 204 is shifted in the +Y direction, the projection position on the wafer WF is also shifted, and therefore, in order to compensate for the positional shift, the position of the fine movement stage on which the DMD 204 is mounted is shifted in the Y direction, the position of the substrate stage 30 is shifted in the Y direction, or the position of the projected image is optically shifted in the Y direction by the projection module PLU.

(Configuration of Control System 600)

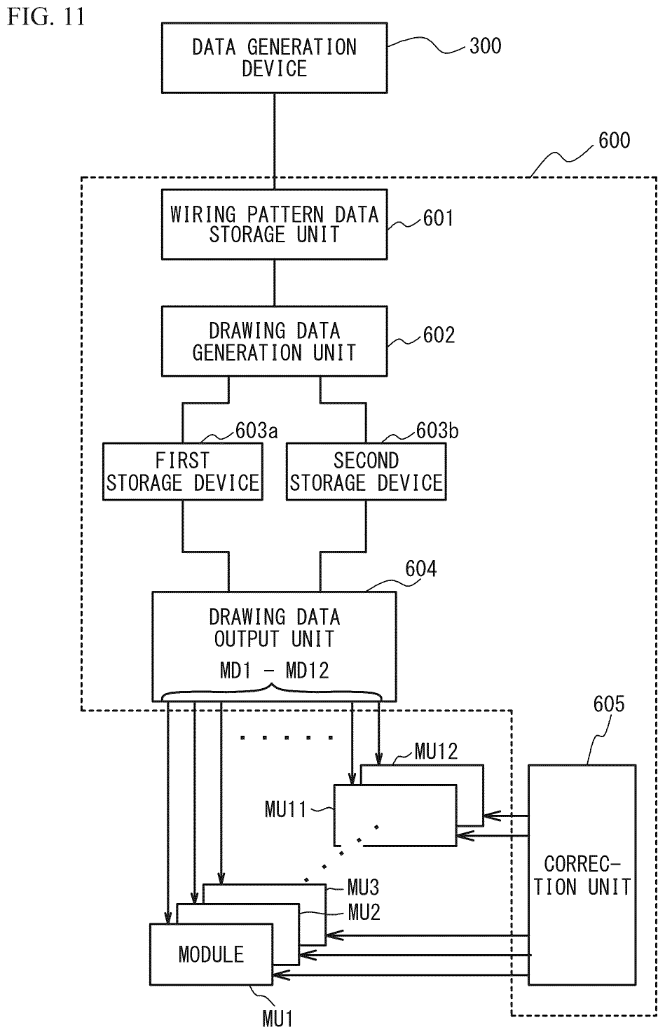

FIG. 11 is a functional block diagram illustrating a functional configuration of the control system 600. As illustrated in FIG. 11, the control system 600 includes the wiring pattern data storage unit 601, the drawing data generation unit 602, a first storage device 603a, a second storage device 603b, a drawing data output unit 604, and the correction unit 605.

The wiring pattern data storage unit 601 stores wiring pattern data for each wafer WF transferred from the data generation device 300.

The drawing data generation unit 602 generates drawing data for controlling the DMD 204 of each of the exposure modules MU1 to MU12 based on the wiring pattern data for each wafer WF stored in the wiring pattern data storage unit 601. The generated drawing data is stored in the first storage device 603a or the second storage device 603b.

The first storage device 603a and the second storage device 603b are, for example, SSDs, and store the drawing data. When the exposure process of the wafer WF is performed using the drawing data stored in the first storage device 603a, the drawing data used in the next exposure process is stored in the second storage device 603b. For example, when the exposure process of the wafer WF is performed using the drawing data stored in the second storage device 603b, the drawing data used in the next exposure process is stored in the first storage device 603a.

The drawing data output unit 604 sends the drawing data MD1 to MD12 to the DMDs 204 of the exposure modules MU1 to MU12, respectively.

As described above, when the wafer WF is placed on the substrate holder PH with being shifted from the design position, the correction unit 605 corrects the positional shift of the wafer WF from the design value by controlling at least one of the driving of the fine movement stage on which the DMD 204 is mounted or the adjustment of the optical system of the projection module PLU.

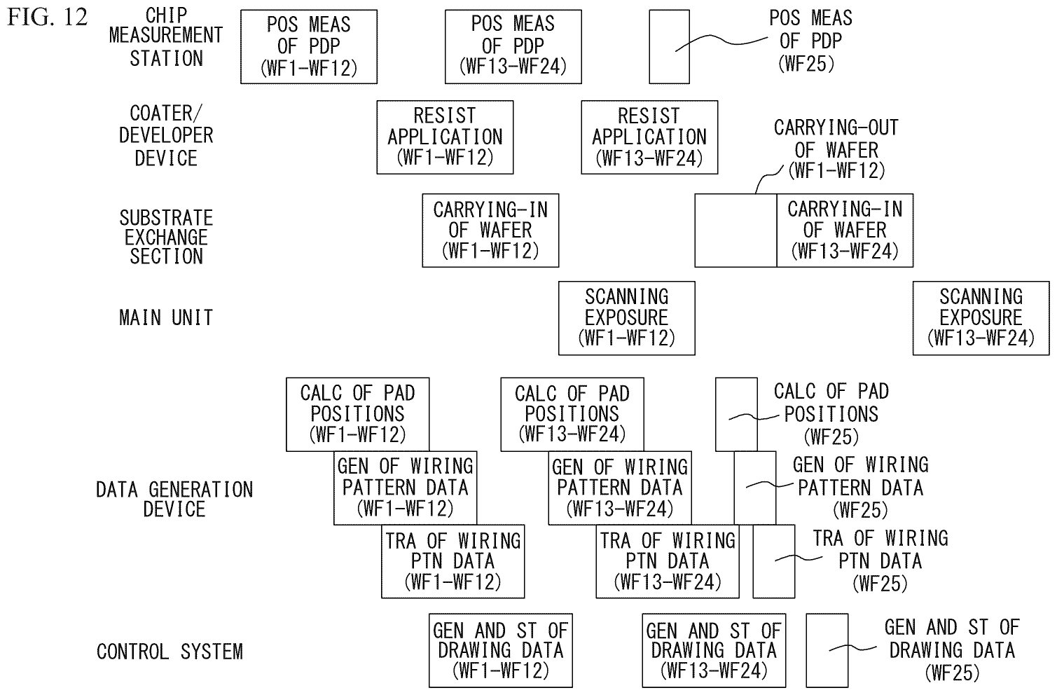

Next, an example of a procedure for forming a wiring pattern of the FO-WLP in the exposure apparatus EX according to the present embodiment will be described. FIG. 12 is a conceptual diagram of a procedure for forming wiring patterns of the FO-WLP in the exposure apparatus EX. In FIG. 12, “POS MEAS OF PDP” means position measurement of predetermined points, “CALC OF PAD POSITIONS” means calculation of pad positions, “GEN OF WIRING PATTERN DATA” means generation of wiring pattern data, “TRA OF WIRING PTN DATA” means transfer of wiring pattern data, and “GEN AND ST OF DRAWING DATA” means generation and storage of drawing data.

In FIG. 12, a case where wafers WF1 to WF25 are set as one lot, and exposure process is performed by dividing the wafers into a first group including the wafers WF1 to WF12, a second group including the wafers WF13 to WF24, and a third group including the wafer WF25 will be described.

As illustrated in FIG. 12, first, in the chip measurement station CMS, the positions of the predetermined measurement points on the chips of the wafers WF1 to WF12 included in the first group are measured. When the measurement in the chip measurement station CMS is finished, the wafers WF1 to WF12 are moved to the coater/developer device DC and then coated with a resist.

The wafers WF13 to WF24 of the second group are carried into the chip measurement station CMS from which the wafers WF1 to WF12 have been carried out, and the positions of the predetermined measurement points on the chips of the wafers WF13 to WF24 are measured.

On the other hand, the data generation device 300 calculates the positions of the pads on the chips based on the position measurement results of the predetermined measurement points on the chips of the wafers WF1 to WF12 in the chip measurement station CMS, and sequentially generates the wiring pattern data based on the calculation results. The data generation device 300 transfers the generated wiring pattern data to the wiring pattern data storage unit 601.

The drawing data generation unit 602 of the control system 600 generates drawing data for controlling each of the exposure modules MU1 to MU12 based on the wiring pattern data stored in the wiring pattern data storage unit 601, and transfers the generated drawing data to, for example, the first storage device 603a.

The drawing data output unit 604 sequentially transfers the drawing data transferred to the first storage device 603a to the exposure modules MU1 to MU12 in accordance with the start of exposure of the first group (wafers WF1 to WF12).

On the other hand, the wafers WF1 to WF12 on which the resist has been applied are sequentially carried into the buffer section PB, arranged on a tray in the substrate exchange unit 2, and then carried into the main unit 1. Thereafter, the wafers WF1 to WF12 are placed on the substrate holder PH and are subjected to scanning exposure.

As described above, in the present embodiment, the drawing data is generated based on the measurement results of the wafers WF1 to WF12 in the chip measurement station CMS using the time required for the resist application in the coater/developer device DC, the arrangement of the wafers WF1 to WF12 on the tray, and the carrying-in of the wafers WF1 to WF12 to the main unit 1.

In parallel with the resist application, wafer loading, and scanning exposure for the wafers WF1 to WF12, the position measurement of the predetermined points, the resist application, the pad position calculation, the generation of wiring pattern data, the transfer of the wiring pattern data, and the generation of drawing data are executed for the wafers WF13 to WF24 included in the second group. At this time, the drawing data generation unit 602 of the control system 600 transfers the generated drawing data to the second storage device 603b. The drawing data transferred to the second storage device 603b is sequentially transferred to the exposure modules MU1 to MU12 in accordance with the start of exposure of the wafers WF13 to WF24.

When the scanning exposure on the wafers WF1 to WF12 is completed, the wafers WF1 to WF12 are carried out from the main unit 1, the wafers WF13 to WF24 are carried into the main unit 1, and are subjected to the scanning exposure. The subsequent processes are the same as those performed on the wafers WF1 to WF12, and thus the description thereof is omitted in FIG. 12.

When the wafers WF13 to WF24 are carried out from the chip measurement station CMS, the wafer WF25 included in the third group is carried in, and the positions of the predetermined points on the chips on the wafer WF25 are measured. The subsequent processes are the same as those performed on the wafers WF1 to WF12, and thus the description thereof is omitted in FIG. 12.

In this way, the processes for the wafers WF1 to WF12, the processes for the wafers WF13 to WF24, and the processes for the wafer WF25 are performed, and the processes for one lot are completed.

[Case where Defect is Detected in Wafer]

As described above, when a defect is detected in any of the wafers WF in the process of forming the wiring patterns on the wafers WF1 to WF25 included in one lot, how to handle the wafer WF becomes a problem.

In the following description, it is assumed that a defect is detected in the wafer WF7 in the chip measurement station CMS in the process of processing one lot including the wafers WF1 to WF25. Here, for example, when a defect (crack, breakage) occurs in any of the chips arranged on the wafer WF, or when a crack occurs in a part of the wafer WF or a part of the wafer WF is broken, the wafer WF is regarded as having a defect.

(Case 1)

In case 1, the wafer WF7 in which a defect has been detected is also carried into the main unit 1, and a reject pattern is exposed onto the wafer WF7 so that the wafer WF7 can be visually identified as a defective wafer when the wafer WF7 is carried out of the exposure apparatus EX. The reject pattern is, for example, a pattern such as a mark “x” or alphabets such as “REJECT”, and is a pattern that allows the wafer WF to which the pattern is exposed to be visually identified.

In this case, the data generation device 300 transmits a reject pattern data for forming a reject pattern as the wiring pattern data for the wafer WF7 to the wiring pattern data storage unit 601. In this case, the drawing data generation unit 602 generates the drawing data using the reject pattern data when generating the drawing data for each of the exposure modules MU8 and MU11 that handle the exposure of the wafer WF7.

Alternatively, the data generation device 300 may transmit information indicating that a reject pattern is to be formed on the wafer WF7 to the wiring pattern data storage unit 601 or the drawing data generation unit 602 without transmitting the wiring pattern data for the wafer WF7 to the wiring pattern data storage unit 601. In this case, the drawing data generation unit 602 generates drawing data using reject pattern data prepared in advance when generating drawing data for each of the exposure modules MU8 and MU11 that handle the exposure of the wafer WF7.

For example, when the data generation device 300 has transmitted the wiring pattern data for the wafer WF7 to the wiring pattern data storage unit 601 and a drawing data generation unit 602 has generated the drawing data for each of the exposure modules MU8 and MU11, the data for the portion corresponding to the wafer WF7 in the drawing data stored in the first storage device 603a or the second storage device 603b is rewritten with the reject pattern data. Instead of the drawing data generation unit 602, the drawing data output unit 604 may rewrite data of the portion corresponding to the wafer WF7 of the drawing data with the reject pattern data.

Thus, when the wafer WF is carried out of the exposure apparatus EX, the wafer WF7 having a defect can be visually identified, and therefore the wafer WF7 can be excluded from the manufacturing process.

(Case 2)

In case 2, the wafer WF7 in which a defect has been detected is also carried into the main unit 1, and scanning exposure is performed without changing the drawing data. In this case, the wiring pattern is formed also in the set including the chip having a defect or the set existing in the portion in which a crack or breakage occurs. Such a set having a defect is removed in an inspection step after the wafer WF is separated into individual pieces by dicing or the like. In this case, not all the sets on the wafer WF7 are wasted, and therefore, the yield can be improved as compared with the case of exposing the reject pattern. A pattern indicating that the wafer WF7 has a set including a chip having a defect or a set existing in a portion in which a crack or breakage has occurred may be exposed on the wafer WF7.

When the wafer WF7 in which a defect has been detected is carried into the main unit 1, it is desirable that the operator can select whether to expose a reject pattern on the wafer WF7 in which the defect exists or to continue the exposure process.

(Case 3)

In case 3, the wafer WF7 in which a defect has been detected is not placed on the substrate holder PH. In this case, the data generation device 300 transmits information indicating that the wafer WF7 is excluded from the lot to the wiring pattern data storage unit 601, and does not transmit the wiring pattern data for the wafer WF7. Since the wiring pattern data for the wafer WF7 is not transferred, the amount of data transferred to the wiring pattern data storage unit 601 can be reduced. Further, the amount of use of the wiring pattern data storage unit 601 can be reduced. In case 3, the data generation device 300 may not necessarily generate the wiring pattern data for the wafer WF7.

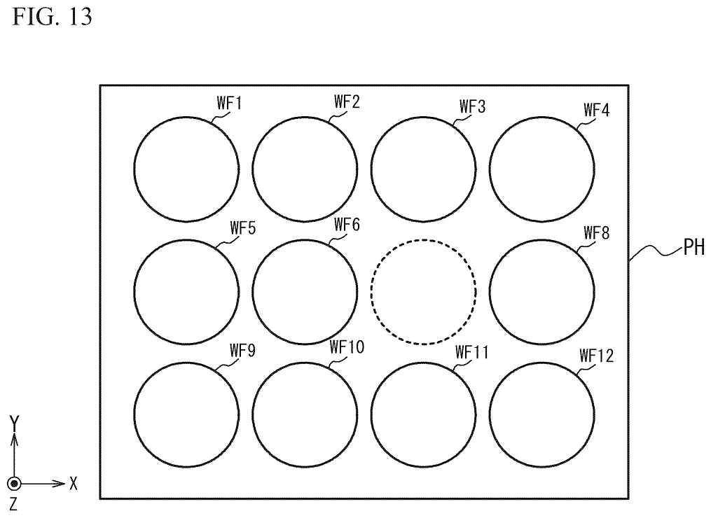

The information indicating that the wafer WF7 is excluded from the lot is also transmitted to the robot RB of the substrate exchange unit 2. Thus, as illustrated in FIG. 13, the robot RB places the wafers WF1 to WF12 on the tray TR while making the position where the wafer WF7 was to be placed empty.

In this case, the drawing data generation unit 602 may generate the drawing data without rewriting the data of the portion corresponding to the wafer WF7, for example, in the template data, when generating the drawing data for each of the exposure modules MU8 and MU11 that handle the exposure of the wafer WF7.

The wiring pattern data for the wafer WF7 may be transferred as usual to generate the drawing data, and the exposure modules MU8 and MU11 may be caused to generate the wiring patterns for the wafer WF7. In this case, since the wafer WF7 is not placed, the wiring pattern image is projected onto the substrate holder PH. Only during the time when the wafer WF7 is exposed, the exposure light may be prevented from being emitted onto the substrate holder PH by using the shutters (not illustrated) of the exposure modules MU8 and MU11. The shutter may be provided in the optical path for guiding light from the delivery fiber FB to the DMD 204, or may be provided in the optical path from the DMD 204 to the wafer WF7.

(Case 4)

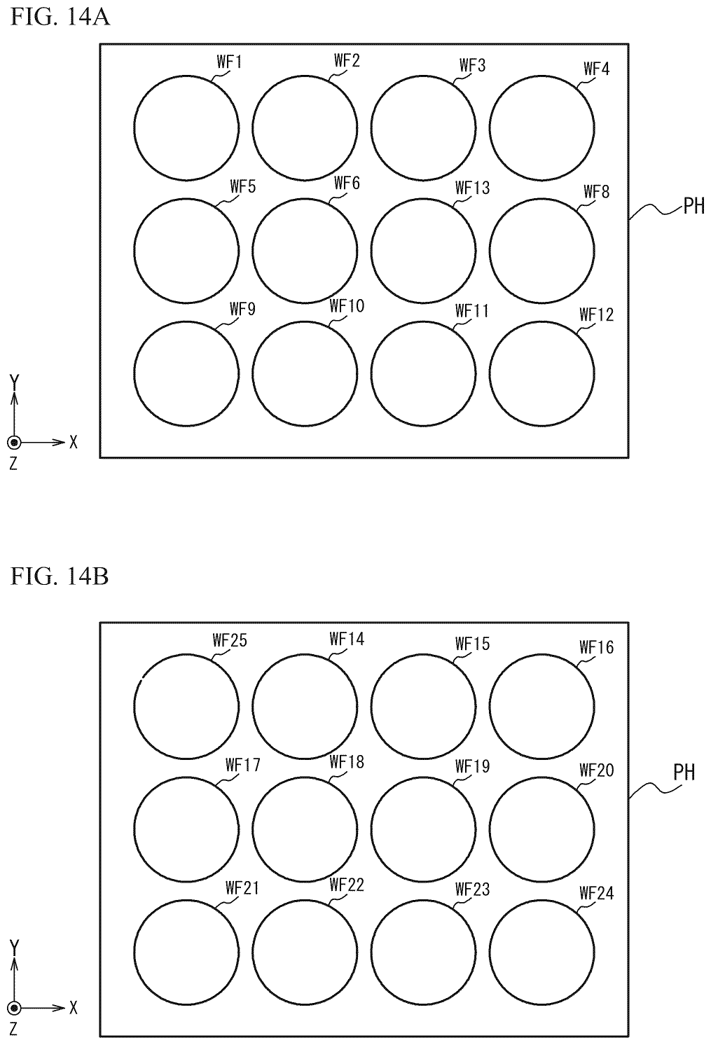

In case 4, the wafer WF7 having a defect is not carried into the main unit 1, and instead of the wafer WF7, the wafer WF13 of the second group different from the first group including the wafer WF7 having a defect is carried into the main unit 1. For example, as illustrated in FIG. 14A, the wafer WF13 included in the second group is placed at a position where the wafer WF7 was to be placed on the substrate stage 30.

In this case, the data generation device 300 transmits information indicating that the wafer WF13 is placed instead of the wafer WF7 and the wiring pattern data for the wafer WF13 to the wiring pattern data storage unit 601. Further, information indicating that the wafer WF13 is placed instead of the wafer WF7 is also transmitted to the robot RB.

The drawing data generation unit 602 generates drawing data for each of the exposure modules MU8 and MU11 that handle the exposure of the wafers WF13 and WF8, using the wiring pattern data for the wafer WF13 and the wiring pattern data for the wafer WF8.

When the data generation device 300 has already transmitted the wiring pattern data to the wiring pattern data storage unit 601 but the drawing data generation unit 602 has not yet generated the drawing data, the drawing data generation unit 602 generates drawing data for each of the exposure modules MU8 and U11 that handle the exposure of the wafers WF13 and WF8, using the wiring pattern data for the wafer WF13 and the wiring pattern data for the wafer WF8.

When the data generation device 300 has already transmitted the wiring pattern data to the wiring pattern data storage unit 601 and the drawing data generation unit 602 has already generated the drawing data, the drawing data generation unit 602 rewrites the portion corresponding to the wafer WF7 in the drawing data stored in the first storage device 603a or the second storage device 603b with the wiring pattern data for the wafer WF13 based on the information indicating that the wafer WF13 is placed instead of the wafer WF7.

In case 4, since the wafer WF13 is excluded from the second group, the wafer WF13 does not exist at a position where the wafer WF13 is to be placed in the second group. In this case, as illustrated in FIG. 14B, the wafer WF25 of the third group is placed at the position where the wafer WF13 was to be placed, and the drawing data is generated.

(Case 5)

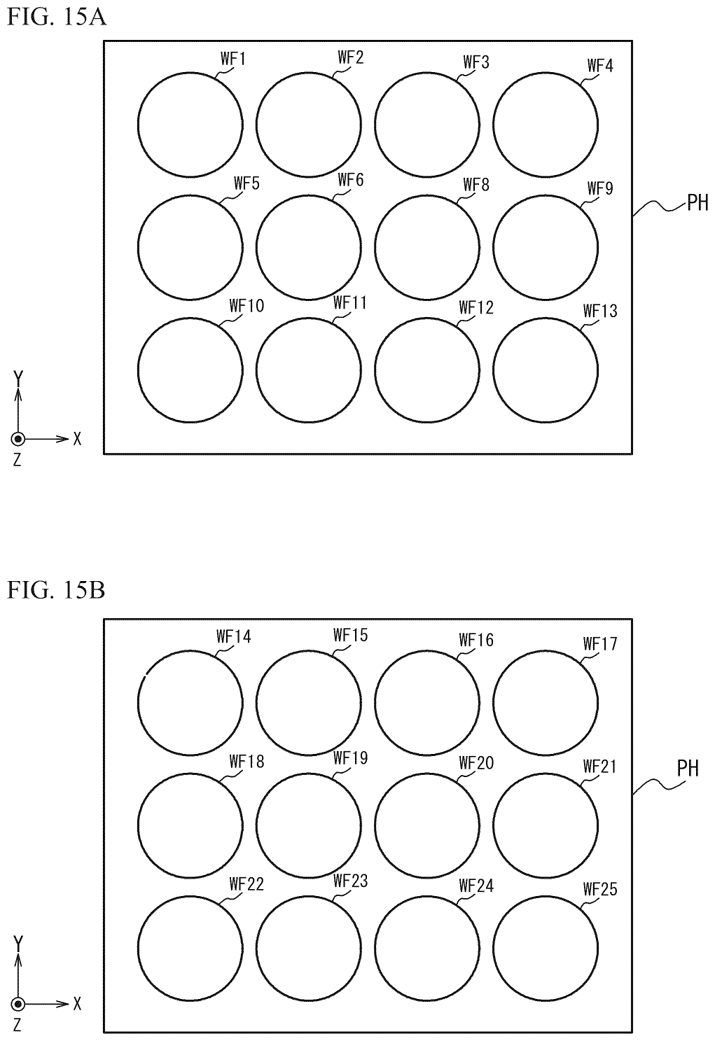

In case 5, the wafer WF7 having a defect is not carried into the main unit 1, and as illustrated in FIG. 15A, the subsequent wafer WF8 was moved over to the place where the wafer WF7 was to be placed, and the wafer WF13 included in the second group is placed at the end.

In this case, the exposure modules MU8 and MU11, that were scheduled to handle the exposure of the wafers WF7 and WF8, are to handle the exposure of the wafers WF8 and WF9, and therefore the drawing data generation unit 602 generates the drawing data for each of the exposure modules MU8 and MU11 based on the wiring pattern data for each of the wafers WF8 and WF9. Since the exposure modules MU3 and MU6, which were scheduled to handle the exposure of the wafers WF9 and WF10, are to handle the exposure of the wafers WF10 and WF11, the drawing data generation unit 602 generates the drawing data for each of the exposure modules MU3 and MU6 based on the wiring pattern data of each of the wafers WF10 and WF11. Since the exposure modules MU9 and MU12, which were scheduled to handle the exposure of the wafers WF11 and WF12, are to handle the exposure of the wafers WF12 and WF13, the drawing data generation unit 602 generates the drawing data for each of the exposure modules MU9 and MU12 based on the wiring pattern data for each of the wafers WF12 and WF13.

In case 5, since the wafer WF13 is excluded from the second group, the wafer WF13 does not exist at the position where the wafer WF13 is to be placed in the second group. In this case, as illustrated in FIG. 15B, the wafers WF14 to WF24 after the wafer WF13 are moved over, and the wafer WF25 is placed at the end.

In cases 4 and 5, the wafer WF25 is included in the second group, and therefore, the exposure process of the third group is eliminated. Therefore, in cases 4 and 5, the number of times of the exposure processing can be reduced in some cases, although it depends on the number of wafers WF included in one lot.

For example, instead of one exposure module MU handling the exposure of multiple wafers WF as in the present embodiment, when each exposure module MU handles the exposure of one wafer WF as illustrated in FIG. 16, wiring pattern data can be used as the drawing data for each exposure module MU. In this case, the wiring pattern data storage unit 601 and the drawing data generation unit 602 may be omitted, and the data generation device 300 may transfer the wiring pattern data for each wafer WF to the first storage device 603a or the second storage device 603b.

When the wafer WF7 has a defect in this configuration, in case 1, the drawing data output unit 604 transfers the reject pattern data to the exposure module WF7 that handles the exposure of the wafer MU7.

In case 3, the drawing data output unit 604 transfers, to the exposure module MU7 that handles the exposure of the wafer WF7, data for turning off or on all the micromirrors 204a of the DMD 204. Alternatively, in case 3, the wiring pattern data for the wafer WF7 is transmitted to the exposure module MU7. In this case, since the wafer WF7 is not placed on the substrate holder PH, the wiring pattern image is projected onto the substrate holder PH.

In case 4, the wiring pattern data for the wafer WF13 is transferred to the exposure module MU7.

In case 5, the wiring pattern data for the wafer WF8 is transferred to the exposure module MU7, the wiring pattern data for the wafer WF9 is transferred to the exposure module MU8, and the wiring pattern data for the wafer WF10 is transferred to the exposure module MU9. Further, the wiring pattern data for the wafer WF11 is transferred to the exposure module MU10, the wiring pattern data for the wafer WF12 is transferred to the exposure module MU11, and the wiring pattern data for the wafer WF13 is transferred to the exposure module MU12.

The control device 600A controls the exposure apparatus EX to take one of the measures described in cases 1 to 5 based on the information of the defective wafer notified from the chip measurement station CMS. When there is a defective wafer, the operator notifies the control device 600A of which of the measures of cases 1 to 5 is to be taken, for example, via a user interface (reception unit) (not illustrated) of the exposure apparatus EX, and the control device 600A can take the measures of cases 1 to 5 based on the measure designated by the operator and the information of the defective wafer. The operator may specify in advance the measure for the defective wafer or may specify the measure every time the defective wafer is detected.

[Case where Defective Element is Generated in DMD 204]

Next, a description will be given of a countermeasure for a case where a defective element is generated in the DMD 204. The defective element is an element that cannot be driven in accordance with the drawing data because, for example, the micromirror 204a of the DMD 204 is stuck in the ON state or in the OFF state.

(Countermeasure 1)

When a defective element is generated in the DMD 204, the exposure module MU including the DMD 204 having a defective element can be prevented from performing exposure. For example, when the exposure modules MU1 to MU12 are arranged as illustrated in FIG. 6 and the DMD 204 of the exposure module MU8 has a defective element, the exposure module MU8 does not perform exposure on the wafers WF7 and WF8 that are to be exposed by the exposure module MU8. In this case, the exposure may be prevented from being performed on the wafers WF7 and WF8 by changing the drawing data so that the DMD 204 does not generate the pattern light, or the exposure may be prevented from being performed on the wafers WF7 and WF8 by, for example, preventing the illumination module ILU from irradiating the DMD 204 with the illumination light.

When the DMD 204 of the exposure module MU8 has a defective element, the exposure module MU11 that also handles the exposure of the wafers WF7 and WF8 is set not to perform exposure on the wafer WF7 nor WF8.

Further, for example, as illustrated in FIG. 16, when the exposure modules MU1 to MU12 are arranged and the DMD 204 of the exposure module MU8 has a defective element, the exposure module MU8 is set not to perform exposure on the wafer WF7 to be exposed by the exposure module MU8.

(Countermeasure 2)

A pattern that makes it clear at a glance that the wafer WF is defective in a subsequent step (visual inspection or macro inspection) may be exposed on the wafer WF that is to be exposed by the exposure module MU including the DMD 204 having a defective element. In this case, the drawing data is changed so that the reject pattern such as a mark “x” is exposed, and is transmitted to the exposure module MU that includes the DMD 204 having a defective element. The DMD 204 having a defective element exposes the reject pattern on the wafer WF by using the elements other than the defective elements.

(Countermeasure 3)

Instead of using the exposure module MU including the DMD 204 having a defective element (hereinafter referred to as a defective exposure module), another exposure module MU (hereinafter referred to as an alternative exposure module MU) may be used for exposure. In this case, the drawing data is changed so that the alternative exposure module MU generates the pattern light that was to be generated by the defective exposure module MU, and the position of the substrate holder PH is controlled so that the pattern light is projected by the alternative exposure module MU onto the substrate onto which the pattern light was to be projected by the defective exposure module MU.

In the case of the countermeasure 3, the alternative exposure module MU to be used when the DMD 204 of each exposure module MU has a defective element is determined in advance. In this case, the offset of the alternative exposure module MU with respect to the defective exposure module MU is calculated in advance, and the substrate holder PH is moved by the calculated offset when the alternative exposure module MU exposes the portion that was to be exposed by the defective exposure module MU. A plurality of exposure modules MU to be used as the alternative when a defective element is generated in the DMD 204 of the exposure module MU may be set for one exposure module MU.

(Countermeasure 4)

The defective element may be ignored and the exposure process may be continued. In this case, instead of discarding the wafer WF, the wafer WF is separated into individual sets by dicing or the like, and then only the set in which a defect such as disconnection of a wiring line connecting chips due to the influence of the defective element is found may be discarded.

For example, when the wiring pattern can be formed using only usable elements (pixels) (elements (pixels) without defects), the wiring pattern may be exposed by driving the fine movement stage of the DMD 204 to shift the projected position of the image of the wiring pattern formed using only the usable elements.

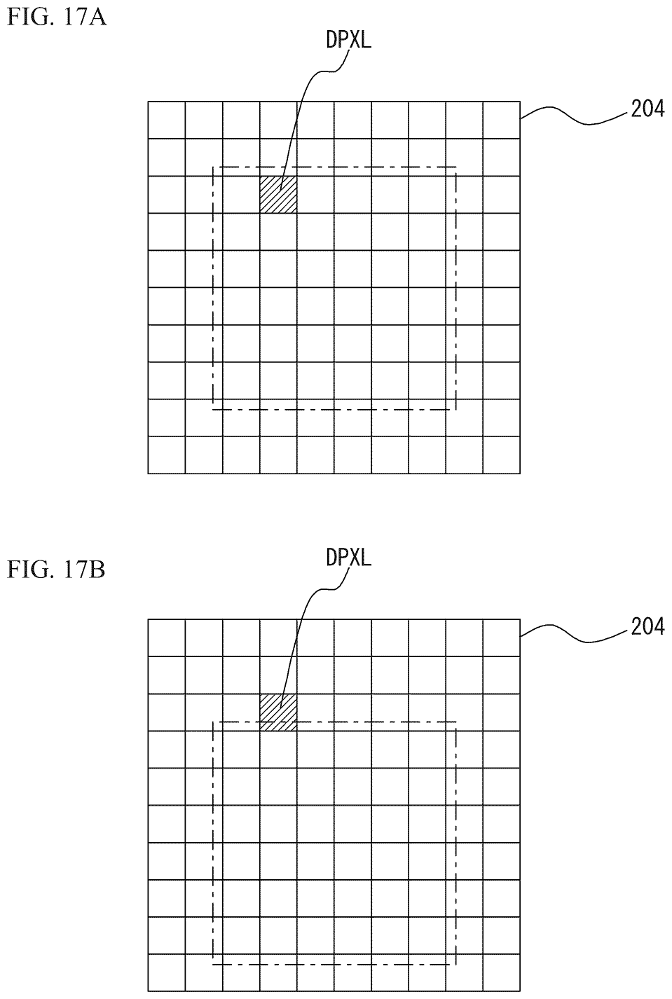

For example, as illustrated in FIG. 17A, it is assumed that the drawing data defines that the wiring pattern is formed using elements surrounded by a chain line among the elements of the DMD 204 and a defective element DPXL exists in the elements for forming the wiring pattern.

In this case, as illustrated in FIG. 17B, by shifting the elements that form the wiring pattern downward by one row, the wiring pattern defined by the drawing data can be generated without using the defective element DPXL. In this case, the elements used to form the wiring pattern are changed, and the shift of the projected position caused by the change of the elements used to form the wiring pattern is corrected by driving the fine movement stage of the DMD 204. The optical system of the projection module PLU may be adjusted together with the driving of the fine movement stage of the DMD 204.

When a defective element exists as described above, the recipe information may be set to generate a wiring pattern using usable elements. Further, when a defective element exists, the operator may be allowed to select whether or not to generate the wiring pattern using usable elements at the timing when the defective element is detected in the DMD 204.

In addition, when a defective element is generated in the DMD 204, which one of the countermeasures 1 to 4 is taken may be selected in the recipe or may be selected by the operator.

When a defect is detected in any of a plurality of wafers WF to be placed on the substrate holder PH and a defective element is generated in the DMD 204, any one of the measures described in the above cases 1 to 5 and any one of the countermeasures 1 to 4 described above may be combined.

In the above embodiment, the data generation device 300 generates the wiring pattern data, and the drawing data generation unit 602 generates the drawing data. However, the data generation device 300 may generate the drawing data, and transmit the generated drawing data to the first storage device 603a and the second storage device 603b of the control system 600.

Note that the disclosures of all publications, international publications, U.S. patent application publications, and U.S. patents relating to exposure apparatuses and the like cited in the above description are incorporated herein by reference.

The embodiments described above are examples of preferred embodiments of the present invention. However, the present invention is not limited thereto, and various modifications can be made without departing from the scope of the present invention.

1. An exposure apparatus comprising:
an exposure module that includes a spatial light modulator and projects pattern light generated by the spatial light modulator onto a substrate; and
a determination unit configured to, in response to that a plurality of substrates scheduled to be arranged on a substrate holder include a first substrate having a defect, determine a plurality of substrates to be arranged on the substrate holder from the plurality of substrates scheduled to be arranged on the substrate holder, based on a predetermined handling method for the first substrate.

2. The exposure apparatus according to claim 1,
wherein the determination unit is configured to determine the plurality of substrates scheduled to be arranged on the substrate holder as the plurality of substrates to be arranged on the substrate holder, and
wherein the exposure module projects a pattern for a defect onto the first substrate, the pattern being generated by the spatial light modulator.

3. The exposure apparatus according to claim 1, wherein the determination unit is configured to determine a substrate other than the first substrate among the plurality of substrates scheduled to be arranged on the substrate holder as the plurality of substrates to be arranged on the substrate holder.

4. The exposure apparatus according to claim 1, wherein the determination unit is configured to determine a substrate other than the first substrate among the plurality of substrates scheduled to be arranged on the substrate holder and a second substrate other than the plurality of substrates scheduled to be arranged on the substrate holder as the plurality of substrates to be arranged on the substrate holder.

5. The exposure apparatus according to claim 4, wherein the second substrate is arranged at a position where the first substrate is scheduled to be arranged on the substrate holder.

6. The exposure apparatus according to claim 4, wherein a substrate different from the first substrate among the plurality of substrates scheduled to be arranged on the substrate holder is arranged at a position where the first substrate is scheduled to be arranged on the substrate holder.

7. The exposure apparatus according to claim 1, further comprising a reception unit configured to receive selection of a handling method for the first substrate.

8. The exposure apparatus according to claim 1, wherein, in response to that the spatial light modulator includes a defective element that cannot be driven in accordance with drawing data, the drawing data is changed so that the spatial light modulator including the defective element does not generate pattern light, or the exposure module is controlled so that pattern light generated by the spatial light modulator including the defective element is not projected.

9. The exposure apparatus according to claim 1,
wherein the exposure module is provided in a plurality, and the plural exposure modules include a first exposure module and a second exposure module different from the first exposure module, and
wherein the exposure apparatus further comprises:
a change unit configured to, in response to that the spatial light modulator of the first exposure module includes a defective element that cannot be driven in accordance with drawing data, change the drawing data so that the second exposure module generates pattern light that is scheduled to be generated by the first exposure module; and a control unit configured to control a position of the substrate holder so that the pattern light generated by the second exposure module is projected onto a substrate onto which the pattern light is scheduled to be projected by the first exposure module.

10. The exposure apparatus according to claim 1, further comprising:
a change unit configured to, in response to that the spatial light modulator includes a defective element that cannot be driven in accordance with drawing data, change the drawing data so that elements other than the defective element among a plurality of elements of the spatial light modulator generate the pattern light; and
a control unit configured to control the exposure module so that the pattern light generated by the elements is projected onto a substrate onto which the pattern light is scheduled to be projected by the spatial light modulator including the defective element.

11. An exposure apparatus comprising:
a first exposure module that includes a first spatial light modulator and projects pattern light generated by the first spatial light modulator onto a substrate; and
a control device configured to generate drawing data for causing the first spatial light modulator to generate respective patterns to be exposed on a plurality of substrates actually arranged on a substrate holder,
wherein the control device is configured to, in response to that the first spatial light modulator includes a defective element that cannot be driven in accordance with the drawing data, change the drawing data so that the first spatial light modulator including the defective element does not generate pattern light, or control the first exposure module so that the pattern light generated by the first spatial light modulator is not projected.

12. The exposure apparatus according to claim 11, further comprising:
second exposure module including a second spatial light modulator,
a generation unit
configured to, in response to that the first spatial light modulator includes the defective element, change the drawing data into a changed drawing data so that the second exposure module different from the first exposure module generates pattern light that is scheduled to be generated by the first exposure module; and
a control unit configured to control a position of the substrate holder so that the pattern light generated by the second exposure module is projected onto a first substrate onto which the pattern light is scheduled to be projected by the first exposure module.

13. An exposure apparatus comprising:
an exposure module that includes a spatial light modulator and projects pattern light generated by the spatial light modulator onto a substrate;
a generation unit configured to generate drawing data for causing the spatial light modulator to generate respective patterns to be exposed on a plurality of substrates actually arranged on a substrate holder;
a change unit configured to, in response to that the spatial light modulator includes a defective element that cannot be driven in accordance with the drawing data, change the drawing data so that elements other than the defective element among a plurality of elements of the spatial light modulator generate the pattern light; and
elements is projected onto a first substrate onto which the pattern light is to be projected by the spatial light modulator.

14. The exposure apparatus according to claim 1,
wherein in response to that the plurality of substrates scheduled to be arranged on the substrate holder include the first substrate having the defect, the exposure module projects a pattern for a defect onto the first substrate.

15. The exposure apparatus according to claim 3, further comprising:
arrange the substrate other than the first substrate having the defect on the substrate holder.

16. The exposure apparatus according to claim 7,
wherein the reception unit is configured to select whether or not to continue exposure processing in response to that the plurality of substrates scheduled to be arranged on the substrate holder include the first substrate having the defect.

17. The exposure apparatus according to claim 1, further comprising:
a substrate exchange unit configured to, in response to that the plurality of substrates scheduled to be arranged on a substrate holder include the first substrate having the defect, arrange the plurality of substrates on the substrate holder based on the predetermined handling method.
